(19) United States
(12) Patent Application Publication
(10) Pub. No.: US 2009/0003503 A1
(43) Pub. Date: Jan. 1, 2009

(54) Frequency detector for VCO band selection

(76) Inventor: Rotem Banin, Carmey-Yosef (IL)

Correspondence Address: RYDER IP LAW;C/O INTELLEVATE, LLC, P. O. BOX 52050, MINNEAPOLIS, MN, 55402, US

(21) Appl. No.: 11/824,235

(22) Filed: Jun. 29, 2007

(51) Int. Cl. H03D 3/24

(52) U.S. Cl. 375/376

(57) ABSTRACT

In general, in one aspect, the disclosure describes an apparatus including a multi-band voltage controlled oscillator (VCO), a phase lock loop (PLL) reference clock to track a specific time frame, and an auto band selector (ABS) to count number of VCO output clock periods that occur during the specific time frame for different bands and to select an appropriate band to provide a desired frequency output based on counter results.

### BACKGROUND

A voltage controlled oscillator (VCO) is an oscillator that generates a signal at a frequency determined by an input voltage. A major design parameter in VCOs is the gain (Hz/V) that converts the input voltage to the frequency. In high performance VCOs it may be desirable to have lower gain while maintaining wide frequency coverage. In order to accomplish this, the VCO frequency coverage may be divided into several sub bands, where each band covers part of the whole range. Since the frequency coverage is reduced (per band), the VCO gain can be reduced without limiting the total frequency coverage.

The multi-band VCO is hooked up with a phase locked loop (PLL) which locks the VCO to a reference frequency. The correct sub-band must be selected before the PLL can lock the VCO. Multi-band VCOs may have a significant amount of bands to support wide frequency coverage. The frequency coverage of each band varies due to process, temperature, and dynamic loading variations so that the selection of the appropriate band needs to be take into account all process and/or system level variation.

### BRIEF DESCRIPTION OF THE DRAWINGS

The features and advantages of the various embodiments will become apparent from the following detailed description in which:

FIG. 1 illustrates a high level block diagram of a system for determining output frequency of bands within a multi-band voltage controlled oscillator (VCO), according to one embodiment; and

FIG. 2 illustrates an example flow diagram of an auto band select (ABS) utilized to determine correct band in the multi-band VCO, according to one embodiment.

### DETAILED DESCRIPTION

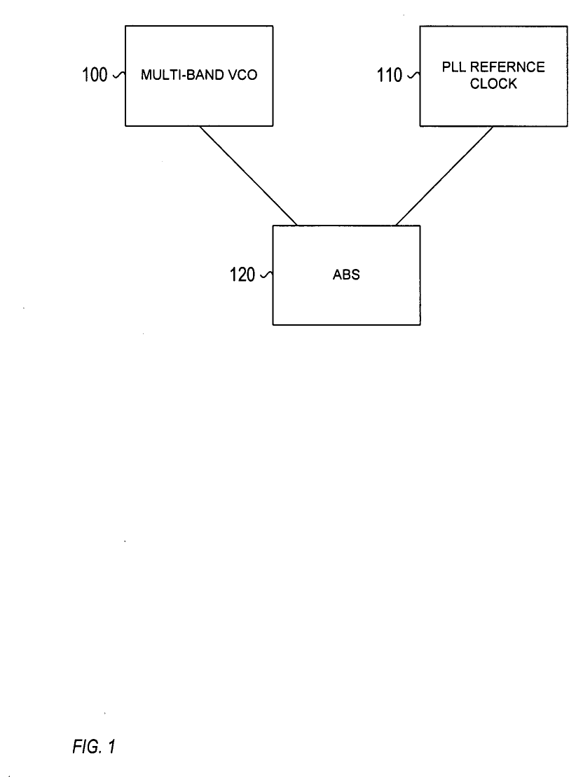

FIG. 1 illustrates a high level block diagram of a system for determining output frequency of bands within a multi-band voltage controlled oscillator (VCO). The system includes a multi-band VCO 100, a phase lock loop (PLL) reference clock 110, and an auto band selector (ABS) 120. The ABS 120 may use a counter (not separately illustrated) to count the number of VCO output clock periods (cycles) that occur during a specific time period. The time period may be accurately generated by the PLL reference clock 110. The level of accuracy in the determination of the VCO band frequencies is the time period. Accordingly, the ABS 120 can make the band frequency measurements very fast, regardless of the frequency of the VCO 100 or PLL reference clock 110. For example, to determine the band frequencies with 2 MHz accuracy the time period should be 500 nsec.

The ABS 120 may be utilized (e.g., in the VCO) to find the correct band in the VCO 100 to produce the desired frequency. The ABS 120 calculates an expected value (the number of VCO clock periods within the time frame) for the desired frequency of the VCO 100. The VCO input voltage control is fixed to a predetermined value. The ABS 120 selects an initial band and counts the number of VCO clock periods that occur during the given time period (generated from the reference clock) with the counter. The ABS 120 compares the counter value to the expected value to determine how the frequency of the band selected compares to the desired frequency. If the counter value is greater than the expected value the frequency for that band is greater than the desired frequency so a next band selected should have a lower frequency range (e.g., lower band). If the counter is less than the expected value the frequency for that band is less than the desired frequency so a next band selected should have a higher frequency range (e.g., higher band).

The next band selected may be based on any number of search criteria (e.g., linear, binary, complex). Eventually the ABS 120 will converge on the band that is guaranteed to cover the desired frequency. The amount of time that it takes to converge on the desired frequency is dependent on various parameters including the number of VCO bands, the search criteria used, and the desired frequency resolution (time period).

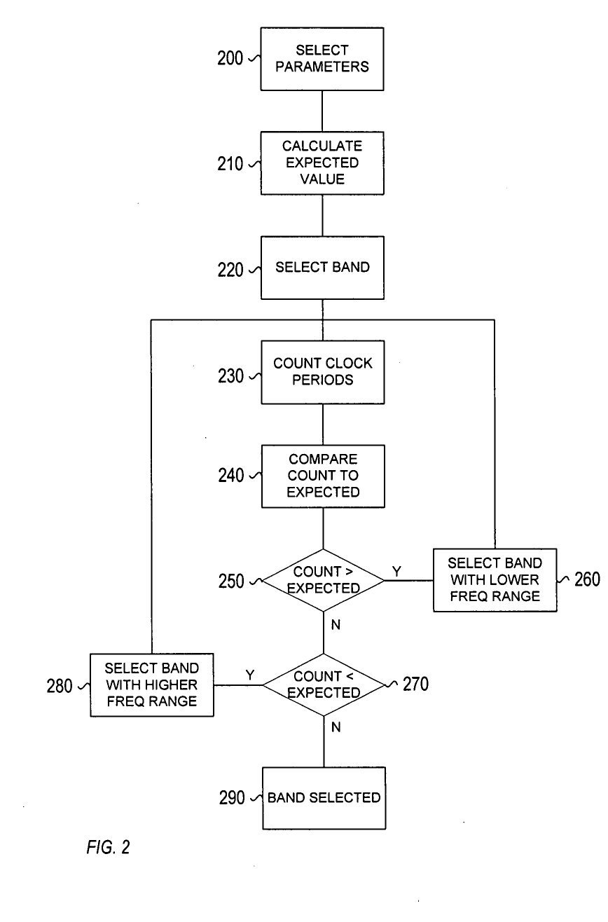

FIG. 2 illustrates an example flow diagram of the ABS. Initially, parameters such as the desired frequency and the input voltage of the VCO, and the time period are selected 200. The expected value (the number of VCO clock periods within the time frame) is then calculated for the desired VCO frequency 210. An initial band is selected 220 and the number of clock periods for that band frequency are counted for the time period 230. The counted value is compared to the expected value 240. A determination is made as to whether the count is higher then the expected value 250. If the count is higher (250 Yes) the frequency of the selected band is too high and a band with a lower frequency range is selected 260. The clock periods are then counted for the lower band 230. If the count is not higher (250 No) a determination is made as to whether the count is lower then the expected value 260. If the count is lower (260 Yes) the frequency of the selected band is too low and a band with a higher frequency range is selected 280. The clock periods are then counted for the higher band 230. If the count is not lower (260 No) the count is equal to the expected value and the band is determined 290.

It should be noted that the count may never actually equal the estimated value as the count for selected bands may bounce back and forth between higher and lower. A decision may then be made that the search is over and that you are close enough and select one of the bands.

The flow is not limited to the steps or the order illustrated. Rather steps could be added, removed, combined or broken out and the order can be changed without departing from the current scope, as long as the flow resulted in a determination of the band by counting the clock cycles for a predefined time.

Although the disclosure has been illustrated by reference to specific embodiments, it will be apparent that the disclosure is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

What is claimed:

1. An apparatus comprising
a multi-band voltage controlled oscillator (VCO);
a phase lock loop (PLL) reference clock to track a specific time frame; and
an auto band selector (ABS) to count number of VCO output clock periods that occur during the specific time frame for different bands and to select an appropriate band to provide a desired frequency output based on counter results.

2. The apparatus of claim 1, wherein the ABS is to determine an expected count of VCO output clock cycles for the desired frequency output and to compare the counter results for bands to the expected count.

3. The apparatus of claim 2, wherein the ABS is to compare the counter results for a selected band to the expected value and to make a selection about a new band based on the comparison.

4. The apparatus of claim 3, wherein the ABS is to select a band with higher frequency range if counter results are lower than the expected count.

5. The apparatus of claim 3, wherein the ABS is to select a band with lower frequency range if counter results are higher than the expected count.

6. The apparatus of claim 3, wherein the ABS selects the next band based on a linear search criteria.

7. The apparatus of claim 3, wherein the ABS selects the next band based on a binary search criteria.

8. The apparatus of claim 1, wherein the specific time frame is based on desired frequency resolution in determination of appropriate frequency band.

9. A method comprising
selecting a desired multi-band VCO output frequency;
selecting a desired frequency resolution for the VCO output frequency;
generating a time frame based on the frequency resolution;
monitoring the time frame using a PLL reference clock;
calculating an expected value for number of VCO output clock cycles to occur within the time frame for the desired frequency output;
selected an initial band of the VCO;
counting number of VCO output clock cycles to occur with the time frame for the selected band;
comparing the count for the selected band with the expected value;
adjusting the band based on the comparison; and
selecting a band for the desired output frequency.

10. The method of claim 9, wherein the adjusting includes selecting a band with higher frequency range if the comparing determines count is less than the expected value.

11. The method of claim 9, wherein the adjusting includes selecting a band with lower frequency range if the comparing determines count is greater than the expected value.

12. The method of claim 9, wherein the adjusting includes using a linear search criteria.

13. The method of claim 9, wherein the adjusting includes using a binary search criteria.
